(19) United States
(12) Patent Application Publication
(10) Pub. No.: US 2003/0124794 A1
(43) Pub. Date: Jul. 3, 2003

(54) Electronic component incorporating an integrated circuit and planar microcapacitor

(75) Inventor: Lionel Girardie, Eybens (FR)

Correspondence Address: HESLIN ROTHENBERG FARLEY & MESITI PC, 5 COLUMBIA CIRCLE, ALBANY, NY, 12203, US

(73) Assignee: MEMSCAP

(21) Appl. No.: 10/318,892

(22) Filed: Dec. 13, 2002

(30) Foreign Application Priority Data
Dec. 31, 2001 (FR) 01 17069

(51) Int. Cl. H01L 21/8242; H01L 21/20

(52) U.S. Cl. 438/250; 438/393; 257/306

(57) ABSTRACT

Electronic component incorporating an integrated circuit made in a substrate (1) and a planar capacitor, characterized in that the capacitor is made on top of a metallization plane of the component, this metallization plane forming a first electrode (2) of the capacitor, and in that the capacitor comprises:

a first oxygen diffusion barrier layer (5) deposited on top of the metallization plane (2);

a stack (6) of several different oxide layers, each layer having a thickness less than 100 nanometres, the stack being deposited on top of the first barrier layer (5);

a second oxygen diffusion barrier layer (7) deposited on top of the stack of oxide layers (6);

a metal electrode (20) present on top of the second barrier layer (7).

### TECHNICAL FIELD

The invention relates to the technical field of microelectronics. More specifically, it relates to an electronic component incorporating a microcapacitor which can be used within the scope of applications, for example radiofrequency applications. This capacitor may be made on the upper face of the substrate of the component, or else inside the substrate itself, at the core of an integrated circuit. The design of such a capacitor makes it possible to obtain particularly high capacitance values.

### PRIOR ART

The production of microcapacitors on silicon substrates has already been the subject of some development.

Thus, document FR 2 801 425 describes a microcapacitor, the dielectric portion of which consists of two layers of different materials, and more specifically, on the one hand, of silicon dioxide, and on the other hand, of silicon nitride. Such microcapacitors have the drawback of being limited in their capacitance value. This is because the dielectric constants (εᵣ) of the materials used are relatively low, typically about 4.1 for silicon dioxide and 7 for silicon nitride. Thus, in applications requiring a very high capacitance, it is necessary to produce layers of low thickness. The risk is then that the proximity of the electrodes would result in undesirable spurious phenomena, by means of the tunnel effect. The dielectric behaviour of such thin layers must also be mentioned among the drawbacks of such capacitors, since they cause avalanche effects.

Moreover, in the publication of U.S. patent application Ser. No. 2001/0041413, a method making it possible to produce an RC circuit on a silicon semiconductor substrate was described. More specifically, the resistor and the capacitor are obtained from the same layer of tantalum. Part of this tantalum layer is used to form the resistor of the RC circuit. The capacitor is obtained by oxidation of a zone of the tantalum layer located vertically in line with one of the electrodes of the capacitor. More specifically, this oxidation is obtained by diffusion of oxygen over this specific zone. After oxidation of the tantalum into tantalum oxide, a dielectric layer is thus obtained, which can be covered with a second electrode in order to form the capacitor. Nevertheless, it is noted that a capacitor of this sort has a number of drawbacks due to the fabrication method. Thus, the integrity of the dielectric is poorly controlled since the tantalum is predominantly oxidized on the side of the face receiving the oxygen stream. The result is poor homogeneity of the dielectric layer, which could be the source of defects and, at minimum, a large variability in the capacitance values.

One of the objects of the invention is to make it possible to produce microcapacitors having high capacitance values.

Another object is to obtain these high capacitance values with layers of a thickness greater than those in which there is a risk of tunnel effects appearing.

Another object of the invention is to provide a fabrication method which makes it possible to control the capacitance values, and to adapt them according to the application.

Another object of the invention is to make it possible to produce these microcapacitors on substrates incorporating an integrated circuit, for which the maximum temperatures during the production methods must be relatively limited, and typically less than 400° C.

### SUMMARY OF THE INVENTION

The invention therefore relates to an electronic microcomponent incorporating an integrated circuit made in a substrate, and a planar capacitor.

According to the invention, the capacitor is made on top of a metallization plane of the component, this metallization plane forming a first electrode of the capacitor. Furthermore, the capacitor comprises:

a first oxygen diffusion barrier layer deposited on top of the metallization plane;

a stack of several different oxide layers, each layer having a thickness less than 100 nanometres, the stack being deposited on top of the first barrier layer;

a second oxygen diffusion barrier layer deposited on top of the stack of oxide layers;

a metal electrode present on top of the second barrier layer.

In other words, the invention consists in using a nanolaminated structure of various oxides, separated from the metal electrodes by an oxygen diffusion barrier layer as a dielectric for the capacitor.

The use of various oxide layers makes it possible to obtain overall values of relative permittivity which make it possible to obtain capacitances greater than 10 nF/mm². These various oxide layers may be obtained by deposition methods not necessarily requiring high-temperature annealing operations, which makes them compatible with the production of these capacitors in combination with integrated circuits.

In practice, the capacitor may be made on the upper plane of the substrate. In this case, the metallization plane corresponds to an upper plane of the substrate, and for example to an interconnect pad.

The capacitor may also be made inside the integrated circuit. In this case, the metallization plane forming the first electrode corresponds to an internal metallization plane of the integrated circuit.

Various oxides may be used to form the stack of dielectric layers. In particular, materials chosen from the following group may be mentioned: HfO₂, Ta₂O₅, ZrO₂, La₂O₃ in which La represents a lanthanide, Y₂O₃, Al₂O₃₁ TiO₂, MgO, CeO₂, Nb₂O₅, strontium titanates and tantalates (STO), barium strontium titanates (BST), strontium bismuth tantalates (SBT), lead zirconium titanates (PZT) and barium strontium tantalate (BST). Among these materials, tantalum pentoxide Ta₂O₅ whose relative permittivity is about 26, and titanium dioxide TiO₂ whose relative permittivity is about 80, may be favoured. These materials may be used in various combinations. The number of layers in the stack and the thickness of each of these layers are determined according to the electrical properties, especially the capacitance, that it is desired to obtain.

In practice, it is preferable that the oxide layers are obtained by the technique known by the name ALD (Atomic Layer Deposition). This is because, by virtue of this technique, it is possible to control the thickness of each of these layers, which makes it possible to guarantee good homogeneity of this thickness over the entire surface of the dielectric layer, and therefore to avoid sources of defects. The ALD technique may use several sources of materials, that is solid, liquid or gaseous sources, making it very flexible and evolutive. Moreover, it uses precursors which are the vectors of the chemical surface reaction, and which transport the material to be deposited. More specifically, this transport implements a process of chemical sorption of the precursors on the surface to be coated, by creating a chemical reaction with ligand exchange between the surface atoms and the precursor molecules. The principle of this technique prevents the adsorption of the precursors or their condensation and therefore their decomposition. Nucleic sites are continually created until the saturation of each reaction phase, between which purging with inert gas makes it possible to renew the process. The ALD technique differs from the technique widely used in the semiconductor industry of CVD (Chemical Vapour Deposition) in that the precursors used in ALD are very reactive and do not decompose on the surface. The uniformity of the deposition is ensured by the reaction mechanism and not by the reactants used, as is the case in CVD, while the thickness of the layers deposited by ALD depends on each cycle of chemical sorption of the precursors. For the ALD technique, chlorites and oxychlorides such as ZrCl₄ or MoCl₅, metallocenes such as ZrCp₂Cl₂, metal acyls such as Al(CH₃)₃, beta-diketonates such as La(thd)₃, or alkoxides such as Ta-ethoxide will preferably be used as precursors.

Advantageously, in practice, the materials used to form the layers providing a barrier to the diffusion of oxygen are made from materials chosen from the group comprising: WSi₂, TiSi₂, CoSi₂, WN, TiN, TaN, NbN, MoN, TaSiN, TiAlN and TaAlN. These materials are deposited by the ALD technique.

In a preferred embodiment, titanium nitride (TiN) may be preferred.

The choice of this material makes it possible to limit any diffusion of oxygen from the oxide layers towards the metal layers forming the electrode.

A capacitor structure of this sort may be used with various connection modes. Thus, the lower electrode may be connected to the rest of the integrated circuit via the metallization plane. This same metallization plane may, for example, be connected to earth.

In another embodiment, the metallization plane may be made accessible by means of a connection pad connected thereto. In this case, the two electrodes of the capacitor are accessible, which makes it possible to include this capacitor in series in an electrical circuit.

In practice, the metal electrode or any additional connection pad may be produced by electrolytic deposition, for example of copper.

### BRIEF DESCRIPTION OF THE FIGURES

A clear understanding of how the invention may be implemented and the advantages resulting therefrom can be gained from the following description of the embodiment, with the aid of the appended figures, in which:

FIGS. 1 to 13 are sectional views of an example of a component made according to the invention, and shown at various production stages.

FIG. 14 is a sectional view of a variant embodiment.

In the figures, the dimensions and especially the thicknesses of the various layers are given by way of illustration to enable the invention to be understood. They may bear no relation to the actual dimensions of the various elements included in the invention.

### EMBODIMENTS OF THE INVENTION

As already stated, the invention relates to a microcapacitor made on an electronic component incorporating an integrated circuit.

This capacitor may be made, as in the illustrated figures, in the upper plane of the substrate. Nevertheless, in other forms of embodiment (not illustrated), this microcapacitor may be made within the substrate itself, in the lower metallization plane of the integrated circuit.

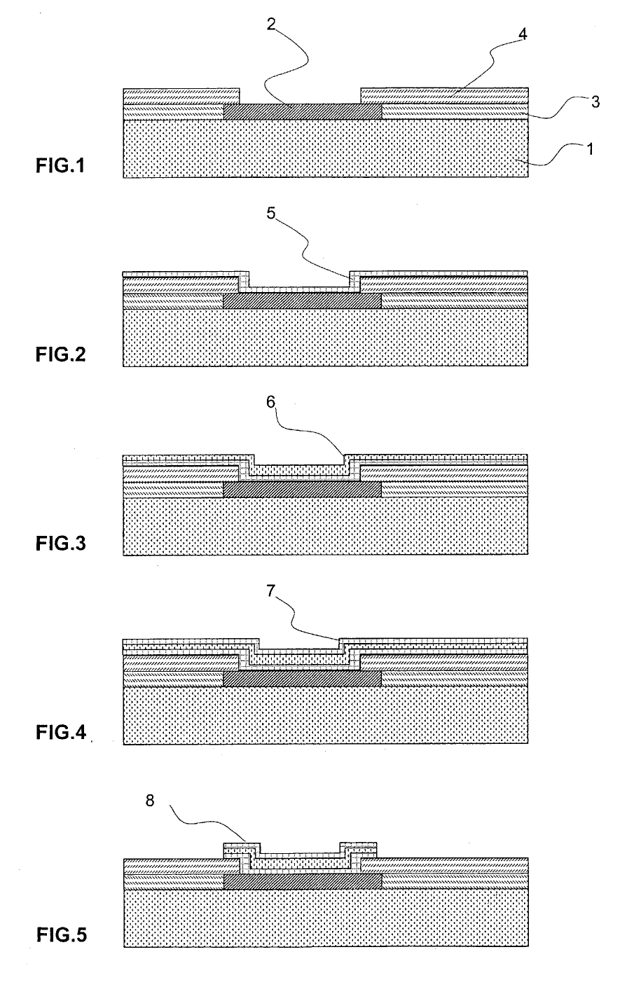

Thus, as illustrated in FIG. 1, the substrate (1) may comprise a connection pad (2) made from a material such as aluminum or copper, or even an aluminum-silicon, aluminum-copper or copper-zinc alloy. In the form illustrated, the substrate (1) is coated with a first passivation layer (3), typically made of SiO₂. This silica layer (3) is coated with a layer of silicon nitride Si₃N₄ making it possible to protect the lower silica layer against exposure to air.

Before proceeding to deposit the various characteristic layers, non-corrosive cleaning is carried out, which makes it possible to remove all the particles which could contaminate the later steps of the method.

In a first step illustrated in FIG. 2, a layer of titanium nitride (TiN) is deposited. This layer (5) has the effect of providing a barrier to the diffusion of oxygen which could oxidize the lower layers. This titanium nitride layer (5) is deposited by ALD, which endows it with very good uniformity of thickness and excellent integrity. This uniformity of thickness makes it possible to ensure that the dielectric layer which will be deposited later is of constant thickness, so as to limit the risks of defect, or diffusion by means of a tunnel effect which could occur should the dielectric layer be too thin.

The titanium nitride may be replaced by a material having similar properties from the materials mentioned above. In particular, a material which has a good affinity with the material used to form the lower electrode (2), possesses excellent adhesion to the lower atomic layers, and allows a good surface reaction with the precursors, will be sought.

Next, as illustrated in FIG. 3, a plurality of oxide layers are deposited successively. In the form illustrated, the stack of these various oxide layers (6) is illustrated in the form of a single layer. However, this stack may comprise a great number of elementary layers, which may be as many as several tens of layers. These various oxide layers have a thickness which can range from 5 Å to a few tens of nanometres. Among the materials giving good results, stacks of layers of alumina Al₂O₃ and of titanium dioxide TiO₂ have been noted. Good results are also obtained with nanolaminates made from layers of tantalum oxide Ta₂O₅ and of titanium dioxides TiO₂. Titanium dioxide, or even zirconium dioxide, are in an amorphous state at temperatures of about 300 to 400° C. which are used during the deposition step by the ALD technique. At these temperatures, the tantalates Ta₂O₅ are in an unstable phase and combining them with the zirconium or titanium dioxide layers provides some phase stability for the Ta₂O₅.

Next, as illustrated in FIG. 4, a second layer of titanium nitride TiN is deposited. This additional layer (7) may be produced by using the various materials described above, as soon as the effect of providing a barrier against oxygen is obtained, while preserving a good quality of attachment to the metal layer which will be deposited later.

Next, the various lithography and etching steps, making it possible to remove the various layers (5, 6, 7) deposited on top of the substrate, are carried out. These etching steps are successive in order, initially, to remove the titanium nitride layer except for in the zone (8) vertically in line with the connection pad (2). This etching may, for example, be carried out with CCl₄ or CCl₂F₂ or CF₄:H₂. This first etching step is then followed by an etching step, for example using fluorinated gases such as SF₆, making it possible to remove the nanolaminated oxide layer (6). After a final step of etching the titanium nitride layer (5), the structure illustrated in FIG. 5 is obtained.

Subsequent steps make it possible to define the upper electrode and the associated connection pad.

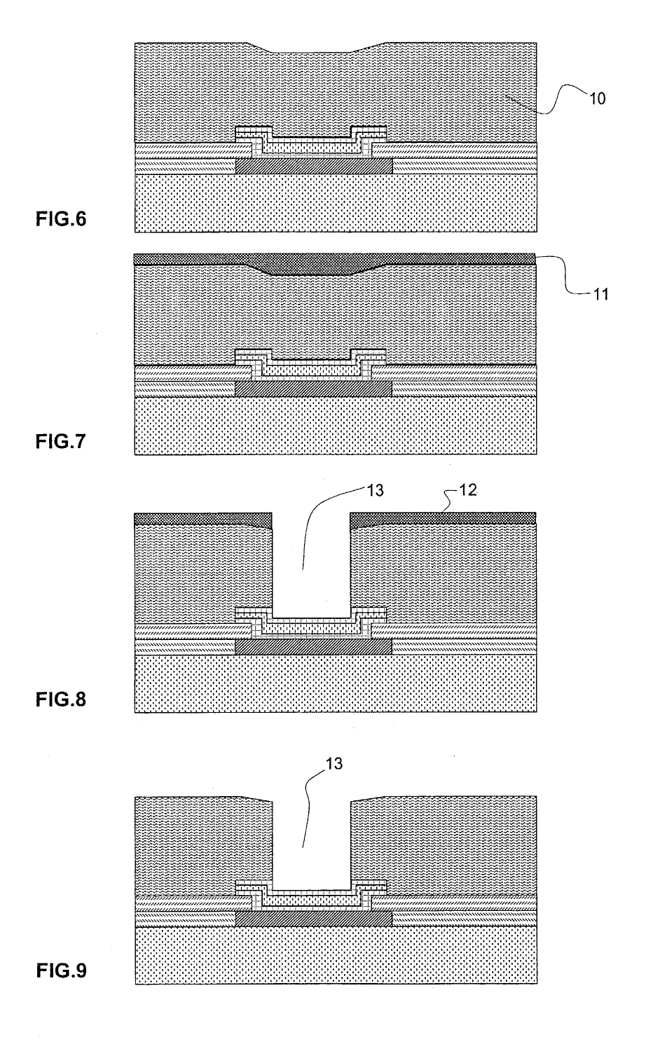

Thus the deposition of a layer (10) of resin of the benzocyclobutene (BCB) type is carried out next, as illustrated in FIG. 6, by the spin-on deposition technique. This BCB layer typically has a thickness greater than 500 nm.

Next, the deposition of a layer (11) covering the BCB layer (10) is carried out, as illustrated in FIG. 7, forming a hard mask. The materials used to form this hard mask (11) may be relatively varied. They may especially consist of silicon carbide, but also chromium, tungsten silicide (WSi₂), or else titanium nitride or silica or even silicon nitride. Preferably, silicon nitride is used.

Next, a lithography step then an etching step is carried out in order to define an opening in the hard mask layer (11), vertically in line with the lower electrode. This etching may, for example, be carried out by wet etching using a hypophosphoric acid based solution at a temperature of 180° C. Dry plasma etching may also be used, using a reactive fluorinated gas, such as CF₄:H₂ for example. Next, anisotropic etching of the BCB layer (10) is carried out, vertically in line with the lower electrode (2). This BCB layer (10) may be etched especially by using a mixture of gases such as the mixture (Ar:CF₄:O₂), or the mixture (C₂H₂F₂:CO₂:H₂:Ar) or (SF₆:CO₂:Ar), or even by a radiofrequency plasma using other reagents. When choosing this etching technique, selectivity with respect to the lower titanium nitride layer (7) will be favoured, because it is important that this layer is not too heavily etched when the etching of the BCB is completed. The configuration illustrated in FIG. 8 is then obtained.

Next, the side parts (12) of the hard mask (11) are removed, as illustrated in FIG. 9. In some cases, this removal turns out not to be necessary, especially when the material used for masking is an insulator of the SiO₂ type. On the contrary, in other cases, especially where the hard mask (11) is made of chromium or of tungsten silicide, it is preferable to remove the rest of the hard mask (11). In the particular case where the hard mask is made of titanium nitride, before the hard mask is removed, the titanium nitride layer (7) located vertically in line with the lower electrode (2) will be masked so that this layer providing a barrier to oxygen is not removed at the same time as the rest of the hard mask.

Next, a step of cleaning the hole (13) thus formed is carried out. This cleaning may be carried out by chemical means, using a non-corrosive semi-aqueous mixture. It may also be carried out by dry etching, using a plasma.

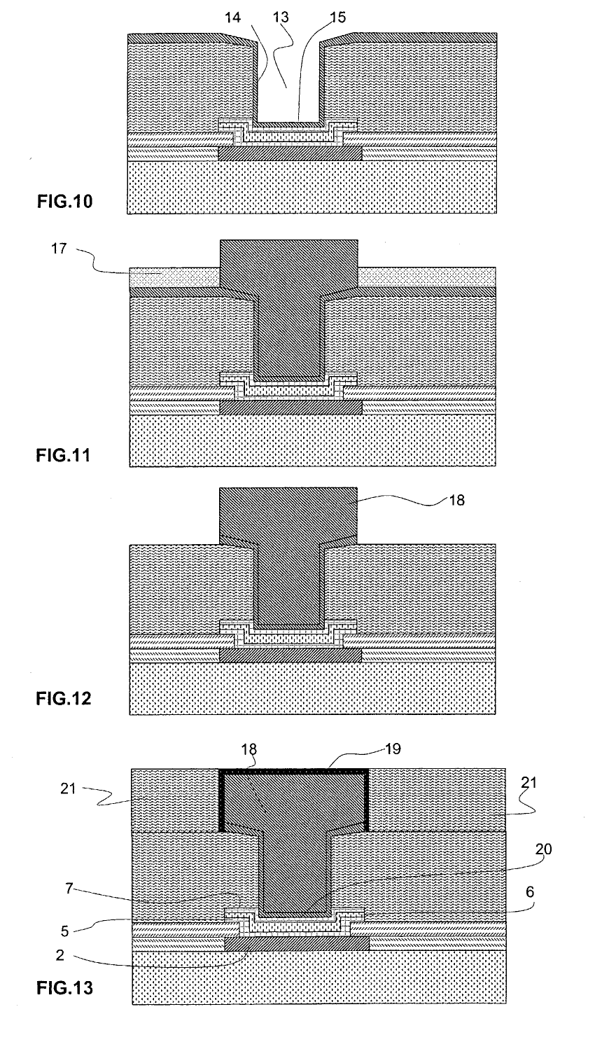

Next, an initial layer (16) of copper is deposited, as illustrated in FIG. 10. This initial layer (16) may be deposited by various techniques, and especially by sputtering, a method also known by the abbreviation IMP-PVD, standing for “Ionized Metal Plasma—Physical Vapour Deposition”. The CVD technique may also be used. An atomic deposition technique (ALD), similar to that used for depositing the various layers of the nanolaminate (6), may also be used.

Next, it is also possible to carry out a step of enriching the initial copper layer (16) by electrolytic means. This enrichment makes it possible to fill the spaces between the pockets of copper which were previously deposited in order to form the initial layer. The surface of this initial layer (16) is therefore smooth, which will favour the subsequent steps of electrolytic deposition of copper. This step makes it possible to increase the thickness of the initial layer inside the via (13), and particularly on the inner faces (14) and at the bottom (15) of the hole (13).

Next, a resin layer (17) is deposited, as illustrated in FIG. 11, which layer is then removed in the zone of the microcapacitor. More specifically, this resin layer is removed in the via (13) and in the periphery of the latter, so as to remain only in the zones (17) illustrated in FIG. 11. Next, electrolytic deposition of copper is carried out, by means of a technique known as “bottom-up filling”, corresponding to a technique used particularly when the structure is a damascene. This technique is also known by the name “bottom-up damascene superfilling”.

This step makes it possible to fill the volume of the via (13), and to cover the upper faces of the component, except for the zones where the initial layer (16) is covered by the resin layer (17).

Any annealing steps may then be implemented.

Next, the resin (17), which has made it possible to define the shape of the pad (18) for connection to the upper electrode (20), is removed, as illustrated in FIG. 12. The initial copper layer (16) is also removed by means of an etching operation, which could be anisotropic wet etching, for example based on a sulphuric acid solution or on a nitric acid solution containing benzotriazole or any other imidazole derivative.

Next, a step of non-corrosive cleaning may be carried out, making it possible to remove all the waste from the resin used during the various steps of the method. This cleaning also makes it possible to remove all particles capable of corroding the copper.

For some applications, it may especially be useful to deposit, as illustrated in FIG. 13, an attachment layer on top of the copper connection pad (18). This attachment layer (19) may, for example, be nickel- or cobalt-based. Next, a layer of polyimide (21) is deposited, up to a height corresponding to the height of the pad (18). This passivation layer (21) may be deposited by spin-on deposition.

The polyimide may also be replaced by another material of the Parylene® type. This passivation layer may then be deposited by PECVD. It is then not necessary to cover the copper pad (18) with a nickel or cobalt layer (19).

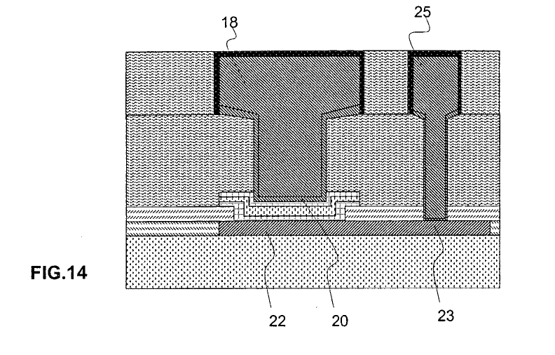

In a variant illustrated in FIG. 14, the metallization plane (22) forming the lower electrode may extend laterally. The zone (23) offset with respect to the capacitor, may then accommodate a connection pad (25) made according to a technique similar to that described for producing the pad (18). The capacitor formed between the upper electrode (20) and the metallization plane (22) is then accessible from the upper face of the substrate, via two connection pads (25, 18).

By way of example, various microcapacitors according to the invention have been made.

Thus, in a first particular example, the stack of oxide layers comprises five layers of zirconium dioxide ZrO₂, each separated by a layer of tantalum oxide Ta₂O₅. Each layer has a thickness of about 10 Å. The capacitance thus obtained is about 28 nF/mm².

In a second example, a stack of nine oxide layers, that is five layers of titanium dioxide TiO₂, each separated by a layer of tantalum oxide Ta₂O₅, was produced. This stack has a capacitance of 38 nF/mm².

It emerges from the above that the microcapacitors according to the invention have many advantages and especially, first and foremost, a capacitance value which is markedly greater than that of existing solutions. These high capacitance values are obtained by maintaining dielectric layer thicknesses which are not likely to allow tunnel-effect or avalanche-effect phenomena appear.

1. Electronic component incorporating an integrated circuit made in a substrate (1) and a planar capacitor, characterized in that the capacitor is made on top of a metallization plane of the component, this metallization plane forming a first electrode (2) of the capacitor, and in that the capacitor comprises:
a first oxygen diffusion barrier layer (5) deposited on top of the metallization plane (2);
a stack (6) of several different oxide layers, each layer having a thickness less than 100 nanometres, the stack being deposited on top of the first barrier layer (5);
a second oxygen diffusion barrier layer (7) deposited on top of the stack of oxide layers (6);
a metal electrode (20) present on top of the second barrier layer (7).

2. Electronic component according to claim 1, characterized in that the metallization plane (2) is located in the upper plane of the substrate.

3. Electronic component according to claim 1, characterized in that the metallization plane corresponds to an internal metallization plane of the integrated circuit.

4. Electronic component according to claim 1, characterized in that the materials used to produce the oxide layers (6) are chosen from the group comprising: HfO₂, Ta₂O₅, ZrO₂, La₂O₃ in which La represents a lanthanide, Y₂O₃, Al₂O₃, TiO₂, MgO, CeO₂, Nb₂O₅, strontium titanate and tantalate (STO), barium strontium titanate (BST), strontium bismuth tantalate (SBT), lead zirconium titanate (PZT) and barium strontium titanate (BST).

5. Electronic component according to claim 1, characterized in that the oxide layers (6) are obtained by atomic layer deposition.

6. Electronic component according to claim 1, characterized in that the layers (5, 7) providing a barrier to the diffusion of oxygen are made from materials chosen from the group comprising: WSi₂, TiSi₂, CoSi₂, WN, TiN, TaN, NbN, MoN, TaSiN, TiAlN and TaAlN.

7. Electronic component according to claim 1, characterized in that it also comprises a connection pad (25) connected to the first electrode (22), thus allowing access to the two electrodes of the capacitor.

8. Method of fabricating a capacitor made on the substrate of an electronic component incorporating an integrated circuit, characterized in that it comprises the following steps consisting, on top of a metallization plane (2) of the component intended to form a first electrode of the capacitor, in:
depositing a first oxygen diffusion barrier layer (5);
depositing a succession (6) of different oxide layers, each layer having a thickness less than 100 nanometres;
depositing a second oxygen diffusion barrier layer (7);
depositing a metal electrode (20).

9. Method according to claim 8, characterized in that the second metal electrode (20) is made by electrolytic deposition.

10. Method according to claim 8, characterized in that the oxide layers (6) are deposited by atomic layer deposition.

11. Method according to claim 10, characterized in that the atomic layer deposition is carried out using precursors chosen from the group comprising: chlorites, oxychlorides, metallocenes, metal acyls, betadiketonates and alkoxides.
